(19) United States
(12) Patent Application Publication
(10) Pub. No.: US 2025/0299993 A1
(43) Pub. Date: Sep. 25, 2025

(54) METHOD AND APPARATUS FOR SECURING A SUBSTRATE

(71) Applicant: Applied Materials, Inc., Santa Clara, CA (US)

(72) Inventors: JIAN LI, Fremont, CA (US); DEENESH PADHI, Santa Clara, CA (US); DAVID FUNG, Saratoga, CA (US); WENHAO ZHANG, Santa Clara, CA (US); KA SHUN WONG, San Jose, CA (US); GANESH BALASUBRAMANIAN, Fremont, CA (US); JUAN CARLOS ROCHA, Santa Clara, CA (US)

(21) Appl. No.: 19/063,135

(22) Filed: Feb. 25, 2025

Related U.S. Application Data
(60) Provisional application No. 63/569,004, filed on Mar. 22, 2024.

(51) Int. Cl. H01L 21/683

(52) U.S. Cl. CPC H01L 21/6833

(57) ABSTRACT

Some embodiments disclosed herein include an apparatus with a pedestal that includes a support surface configured to support a substrate, and an electrode embedded within the pedestal below the support surface. In an embodiment, a sensor is electrically coupled to the electrode, where the sensor is configured to measure a capacitance between the electrode and the substrate when the substrate is provided on the support surface. In an embodiment, the apparatus may further include a radio frequency (RF) filter electrically coupled between the electrode and the sensor.

### CROSS-REFERENCE TO RELATED APPLICATIONS

This application claims the benefit of U.S. Provisional Application No. 63/569,004, filed on Mar. 22, 2024, the entire contents of which are hereby incorporated by reference herein.

### BACKGROUND

### 1) Field

Embodiments of the present disclosure pertain to the field of electrostatic chucks (ESCs).

### 2) Description of Related Art

In semiconductor manufacturing processes, the substrate (e.g., a wafer) is secured to a pedestal by a chuck, such as an electrostatic chuck (ESC). ESCs include one or more electrodes that are biased in order to generate an electrostatic force that attracts the substrate. In a monopolar ESC, a single electrode is positively or negatively biased, and plasma within the chamber completes the circuit by providing a source of electrons to the substrate in order to negatively bias the substrate. In a bipolar ESC, a first electrode is positively biased and a second electrode is negatively biased. This allows for the charge to redistribute within the substrate (without the need of a plasma) in order to provide an attractive force between the ESC and the substrate.

Often, the substrate is curved (or bowed) when a substrate is initially placed on the ESC. The curvature of the substrate may be the result of stresses within one or more films deposited on the substrate, coefficient of thermal expansion mismatch, or the like. The curvature may be oriented so the concave surface of the substrate faces towards the ESC or away from the ESC.

### SUMMARY

Some embodiments disclosed herein include an apparatus with a pedestal that includes a support surface configured to support a substrate, and an electrode embedded within the pedestal below the support surface. In an embodiment, a sensor is electrically coupled to the electrode, where the sensor is configured to measure a capacitance between the electrode and the substrate when the substrate is provided on the support surface. In an embodiment, the apparatus may further include a radio frequency (RF) filter electrically coupled between the electrode and the sensor.

Some embodiments disclosed herein may include a method that includes initiating a voltage ramp of a voltage applied to an electrode of an electrostatic chuck (ESC) to adjust a position of a substrate relative to the ESC, where the voltage ramp has a first ramp rate. The method may further include measuring a capacitance with a sensor during the voltage ramp, where the capacitance is between the substrate and the electrode of the ESC, and changing the voltage ramp to a second ramp rate when a magnitude of a rate of change of the capacitance is outside of a predetermined range.

Some embodiments disclosed herein may also comprise an apparatus that includes a chamber, and an electrostatic chuck (ESC) within the chamber. In an embodiment, the ESC includes an electrode embedded within a pedestal below a support surface, and a sensor that is electrically coupled to the electrode, where the sensor is configured to measure a capacitance between the electrode and the substrate when a substrate is provided on the support surface. The apparatus may further include a radio frequency (RF) filter electrically coupled between the electrode and the sensor; and a controller communicatively coupled to the sensor, wherein the controller is configured to provide feedback control of a chucking or dechucking process based on capacitance readings provided by the sensor.

### BRIEF DESCRIPTION OF THE DRAWINGS

FIG. 1A is a cross-sectional illustration of a bipolar electrostatic chuck (ESC) with a bowed substrate where the concave surface of the substrate faces away from the ESC, in accordance with an embodiment.

FIG. 1B is a cross-sectional illustration of a bipolar ESC with a bowed substrate where the concave surface faces the ESC, in accordance with an embodiment.

FIG. 1C is a cross-sectional illustration of a bipolar ESC after chucking in order to provide a flat substrate, in accordance with an embodiment.

FIG. 2A is a graph of capacitance between a substrate and an ESC relative to an increasing applied voltage to the ESC for a chucking operation, in accordance with an embodiment.

FIG. 2B is a graph of capacitance between a substrate and an ESC relative to a decreasing applied voltage to the ESC for a dechucking operation, in accordance with an embodiment.

FIG. 3 is an equivalent circuit diagram of an ESC with a capacitance sensor used to control chucking and dechucking operations, in accordance with an embodiment.

FIG. 4A is a graph of the ramp rate of a chucking process over time, in accordance with an embodiment.

FIG. 4B is a graph of the change in capacitance over time when a controlled chucking operation is used in accordance with an embodiment.

FIG. 5A is a schematic illustration of a bipolar ESC before a chucking operation using a capacitance sensor, in accordance with an embodiment.

FIG. 5B is a schematic illustration of the bipolar ESC after a chucking operation using a capacitance sensor, in accordance with an embodiment.

FIG. 6A is a schematic illustration of a monopolar ESC before a chucking operation using a capacitance sensor, in accordance with an embodiment.

FIG. 6B is a schematic illustration of the monopolar ESC after a chucking operation using a capacitance sensor, in accordance with an embodiment.

FIG. 7 is a cross-sectional illustration of a semiconductor processing tool that comprises an ESC with a capacitance sensor, in accordance with an embodiment.

FIG. 8 is a process flow diagram depicting a process for chucking or dechucking a substrate with a closed loop control process that includes capacitance as a feedback input, in accordance with an embodiment.

FIG. 9 illustrates a block diagram of an exemplary computer system of a processing tool, in accordance with an embodiment of the present disclosure.

### DETAILED DESCRIPTION

Electrostatic chucks (ESCs) with capacitive sensing feedback control to enable improved chucking and dechucking are described. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, electrostatic chucks (ESCs) are used in semiconductor manufacturing operations in order to secure the substrate to a pedestal for processing (e.g., deposition processes, etching processes, plasma treatments, heat treatments, etc.). The incoming substrate is often bowed, curved, or otherwise warped due to internal stresses within one or more of the layers provided on the substrate and/or due to coefficient of thermal expansion (CTE) mismatch between materials. During the chucking process, the voltage applied to electrodes in the ESC is sufficient to provide an attractive force that flattens the substrate. However, the substrate can be damaged when this flattening process is implemented rapidly or in an otherwise uncontrolled fashion. For example, thermal shock due to differences in a temperature of the substrate and a temperature of the ESC and/or abrupt mechanical stress changes can result in damage to the substrate. For example, one or more of the layers on the substrate may crack, delaminate, or the like. The substrate itself may also be damaged during the chucking process. Similar damage may occur when an uncontrolled dechucking operation is used to release the substrate from the ESC.

Accordingly, embodiments disclosed herein may include a controlled chucking process in order to minimize or eliminate damage to the substrate and any layers provided on the substrate. Simply reducing the rate at which the voltage increases may be one option. However, this can significantly increase the time needed to chuck the substrate, which decreases throughput. As such, embodiments disclosed herein provide a closed loop control process for chucking and dechucking substrates from an ESC.

In an embodiment, the closed loop control process relies on capacitance measurements between the substrate and the ESC. As the substrate is drawn towards the ESC (as higher voltages are applied), the capacitance between the ESC and the substrate increases. A controller may be configured to dynamically change a voltage ramp rate (e.g., the rate that the voltage is increased (for chucking) or decreased (for dechucking)) in response to changes in capacitance measured by a sensor coupled to the ESC. For example, if the rate of change of the capacitance goes outside of a predetermined range, the voltage ramp rate may be adjusted. By providing closed loop control, the change in capacitance from the beginning of the chucking operation (or dechucking operation) to the end of the chucking operation (or dechucking operation) may be substantially linear. Though, in some embodiments non-linear capacitance values over time may also be suitable. More generally, the closed loop control provides the ability to set a capacitance profile (with respect to time) designed to minimize chucking (or dechucking) induced damage to the substrate, while also minimizing a duration of the chucking (or dechucking) operation. For example, the duration of chucking or dechucking operations disclosed herein may be up to 1.0 second, up to 10 seconds, up to 30 seconds, up to 1.0 minute, or up to 5.0 minutes.

The ability to control the chucking and dechucking process enables ESCs disclosed herein to be used across multiple different types of tools, used within a single tool for multiple different processing recipes, or used at different stages of substrate manufacture. For each different tool, recipe, state of manufacture, a desired chucking profile (with respect to time) may be generated in order to minimize potential damage to the substrate. For example, a bare silicon wafer may be chucked at a different rate than a silicon wafer after many thin film layers have been deposited on the silicon wafer.

Embodiments disclosed herein are compatible with multiple different ESC types. For example, a capacitance controlled feedback loop can be used in either monopolar ESCs or bipolar ESCs, as will be described herein. Additionally, Coulomb ESCs and Johnsen-Rahbek (J-R) chucks may both implement embodiments disclosed herein.

In an embodiment, the closed loop control process based on capacitance can be used throughout the lifespan of an ESC. Typically, an ESC will wear over time and the amount of chucking voltage needs to be increased in order to provide the same chucking force compared to a new ESC. In such instances, the capacitance measurements can be used to determine when a substrate is adequately chucked. For example, when the capacitance does not significantly change in response to voltage increases, it may be determined that the substrate is adequately chucked. This can prevent further damage to the ESC or substrate due to overchucking.

Accordingly, embodiments disclosed herein provide one or more benefits, such as, but not limited to: (1) chucking or dechucking substrates without damaging the substrate and/or layers on the substrate; (2) reducing a duration of the chucking or dechucking operation; (3) providing flexibility to use a single ESC design for multiple different tools, processing recipes, substrate types, etc.; (4) allowing for adjustable operation to account for wear of the ESC; or (5) preventing (or reducing) the need to overchuck a substrate.

Embodiments disclosed herein include a capacitance sensor that is electrically coupled to the one or more electrodes of the ESC. In an embodiment, the capacitance sensor may comprise a direct current (DC) power source with an alternating current (AC) source for detecting the capacitance values. The AC source may have a frequency between approximately 10 kHz and approximately 1,000 kHz. In an embodiment, a filtering component may be provided between the electrodes of the ESC and the sensor in order to filter out radio frequency (RF) components of the signal that may be introduced by a plasma over the substrate.

In embodiments disclosed herein, specific reference is made to substrates that will generally be described as wafers. For example, semiconductor wafers, such as a silicon wafer, may be used as the substrate. The substrates disclosed herein may have form factors of typical semiconductor wafers (e.g., 300 mm, 450 mm, etc.). Though ESCs can be designed to accommodate substrates with any form factor. Additionally, embodiments may include ESCs that are compatible with other substrate materials and form factors. For example, glass substrates, packaging substrates, and/or the like may be used in accordance with embodiments disclosed herein. Some alternative substrates may have rectangular form factors (e.g., panel-based form factors). Further, while embodiments disclosed herein may be applicable to semiconductor manufacturing processes, embodiments are not limited to use within any particular industry.

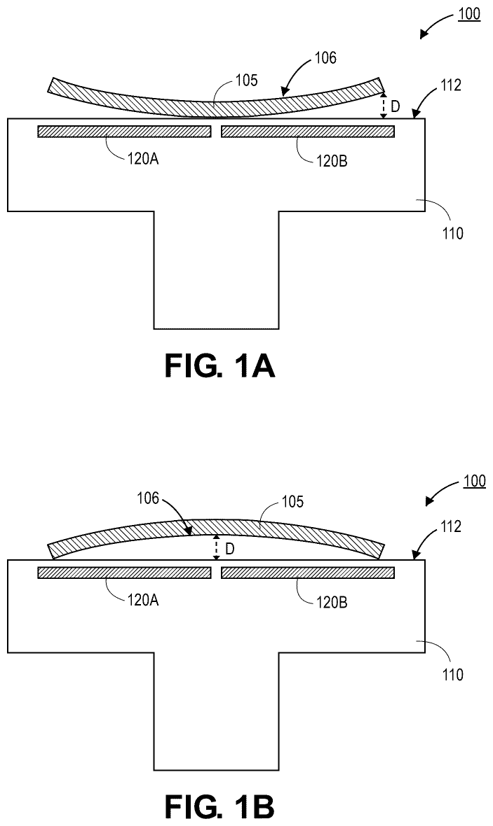

Referring now to FIG. 1A, a cross-sectional schematic illustration of an ESC 100 is shown, in accordance with an embodiment. In an embodiment, the ESC 100 may comprise a pedestal 110. The pedestal 110 may comprise a support surface 112 for supporting a substrate 105. In an embodiment, the support surface 112 of the pedestal 110 may comprise a dielectric material. For example, the support surface 112 may be an oxide, a nitride, or the like. In an embodiment, pair of electrodes 120A and 120B are embedded within the pedestal 110. For example, the electrodes 120A and 120B may be embedded in a dielectric layer of the pedestal 110. In an embodiment, the top surfaces of the electrodes 120A and 120B may be recessed below the support surface 112. The ESC 100 may be configured as a Coulomb ESC 100 or a J-R ESC 100.

In an embodiment, the ESC 100 is a bipolar ESC. Accordingly, the electrodes 120A and 120B may be configured to be oppositely biased in order to induce a chucking force on the substrate 105, as will be described in greater detail below. In an embodiment, the electrodes 120A and 120B may be electrically coupled to a power source (not shown), such as a DC power source. The electrodes 120A and 120B may be configured to be held to voltages between 0V and approximately 2,000V. In the cross-sectional illustration shown in FIG. 1A, two electrodes 120A and 120B are shown. However, bipolar ESCs 100 may include more than two electrodes 120 (e.g., four electrodes 120, eight electrodes 120, or the like).

In an embodiment, the substrate 105 may be any suitable substrate, such as any of the substrate types described in greater detail herein. In an embodiment, the substrate 105 may be bowed, warped, curved, etc. For example, the substrate 105 in FIG. 1A has a bow with a concave surface 106 facing away from the support surface 112. The curvature of the surface 106 may be the result of internal stresses within one or more layers (not shown) that a deposited on the substrate 105, or from CTE mismatches within the substrate 105. Such an orientation of the curvature may sometimes be referred to as having a “concave warpage”.

The warpage of the substrate 105 results in the substrate 105 not sitting flat on the support surface 112. For example, a center of the substrate 105 may contact the support surface 112, while outer edges of the substrate 105 are lifted up from the support surface 112. In an embodiment, a distance D between the support surface 112 and the bottom of the substrate 105 at the outer edge of the substrate 105 may be up to approximately 3.0 mm in some embodiments.

Referring now to FIG. 1B, a cross-sectional schematic illustration of an ESC 100 is shown, in accordance with an alternative embodiment. In an embodiment, the ESC 100 in FIG. 1B may be substantially similar to the ESC 100 in FIG. 1A, with the exception of the substrate 105. Instead of having the concave surface 106 facing away from the support surface 112, the concave surface 106 may face towards the support surface 112. Such an orientation of the curvature may sometimes be referred to as having a “convex warpage”.

Convex warpage of the substrate 105 may result in the outer edges of the substrate 105 contacting the support surface 112, while a center of the substrate 105 is raised up from the support surface 112. For example, a distance D between the support surface 112 and the concave surface 106 on the bottom of the substrate 105 may be up to approximately 3.0 mm in some embodiments.

In the embodiments shown in FIGS. 1A and 1B, the curvatures of the substrates 105 would result in non-uniform processing. Accordingly, the chucking force from the ESC 100 can be used in order to flatten the substrates 105. Typically, the desired chucking voltage is (nearly) instantly applied in order to flatten the substrate 105 by pulling down the outer edges of the substrate 105 (e.g., in the case of concave warpage (FIG. 1A)) or by pulling down the center of the substrate 105 (e.g., in the case of convex warpage (FIG. 1B)). An example of such a chucked substrate 105 is shown in FIG. 1C.

Referring now to FIG. 1C, a cross-sectional schematic illustration of an ESC 100 while voltage is applied is shown, in accordance with an alternative embodiment. In an embodiment, the ESC 100 in FIG. 1C may be similar in structure to either of the ESCs 100 in FIG. 1A or FIG. 1B. However, a voltage has been applied to the electrodes 120A and 120B. For example, the electrode 120A is positively biased, and the electrode 120B is negatively biased. The opposite biases in the electrodes 120A and 120B induces a charge segregation in the substrate 105. For example, electrons may preferentially migrate to the left side of the substrate 105 in FIG. 1C since they are attracted to the positive bias of electrode 120A. This leaves an effective positive bias on the right side of the substrate 105 in FIG. 1C that is attracted to the negative bias of electrode 120B. The force generated by the opposing charges flattens the substrate 105 so that the concave surface 106 is now a flat surface 106′.

However, rapid application of bias to the electrodes 120A and 120B may result in damage 107 to the substrate 105. For example, one or more films or layers on the substrate 105 may crack, delaminate, or experience other damage as a result of the rapid changes in mechanical stress within the layers. Rapid changes in temperature of the substrate 105 (due to increasing contact with a heated pedestal 110) may also result in thermal shock that can lead to damage. In addition to damage that may occur to the layers on the substrate 105, the rapid mechanical and/or thermal changes may also damage the substrate 105.

In FIGS. 1A-1C, examples of a bipolar ESC are shown as an illustrative example. However, it is to be appreciated that monopolar ESCs may also result in similar damage described in FIG. 1C. However, in the case of a monopolar ESC, a single electrode would be biased, and the charge to the substrate is supplied by a plasma (not shown). That is, the chucking for a monopolar ESC may require the presence of a plasma in some embodiments.

Further, while a chucking operation is shown in FIGS. 1A-1C, embodiments may also include dechucking operations. For example, an uncontrolled rapid decrease in voltage applied to the electrodes may result in similar damage due to rapid mechanical and/or thermal changes.

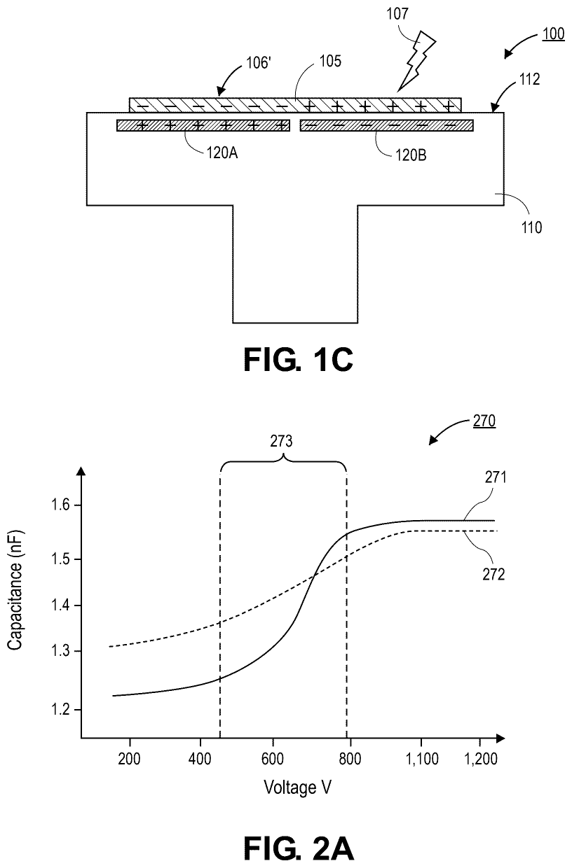

It is to be appreciated that simply reducing the speed of the chucking process is not a suitable solution, especially in high volume manufacturing (HVM) environments. Reducing the rate that voltage is applied to the electrodes without any further considerations is problematic for several reasons. First, slowly increasing the voltage to minimize the effects of thermal and/or mechanical shock will increase the time needed for processing each substrate. That is, substrate throughput will be negatively impacted. Additionally, the relationship between chucking voltage and the gap between the ESC and the substrate may not be linear. Accordingly, if a constant voltage change were applied to the ESC, there may still be time periods where the distance between the ESC and the substrate changes too fast, and damage may occur. This non-linear characteristic is shown in FIGS. 2A and 2B.

Referring now to FIG. 2A, a plot 270 of capacitance versus voltage is shown for a concavely warped substrate 271 and a convexly warped substrate 272 during a chucking operation. As can be appreciated, the capacitance value can be correlated to the average distance between the substrate and the ESC. An average distance is used since the warpage will result in different points of the substrate being different distances from the ESC. As can be appreciated, as the average distance between the substrate and the ESC decreases, the capacitance will increase.

With respect to the line of the concavely warped substrate 271, there is a rapid increase in capacitance in region 273 compared to rates of capacitance increases outside of region 273. If the voltage ramp rate were tuned to reduce the negative effects generated during region 273, the beginning of the chucking operation and the end of the chucking operation would be much slower than necessary. Alternatively, if the voltage ramp rate were tuned to the beginning or the end of the chucking operation, then the middle region 273 may still exhibit a change in curvature at a rate that may lead to damage of the substrate. With respect to the line for the convexly warped substrate 272, the change in capacitance within region 273 is not as extreme as the change in capacitance of the concavely warped substrate 271. However, there is still a different rate of capacitance change which may result in damage if the chucking process is uncontrolled.

Referring now to FIG. 2B, a plot 275 of capacitance versus voltage is shown for a concavely warped substrate 276 and a convexly warped substrate 277 during a dechucking operation. That is, the voltage applied initially is high, and the voltage is reduced in order to let the substrate return to a warped shaped. Similar to the plot 270 in FIG. 2A, the lines do not exhibit a linear change. The different slopes of the lines can result in challenges with choosing the proper ramp rate in order to safely dechuck the substrate in a timely fashion appropriate for HVM environments.

In the illustrated embodiment, the shape of lines for the concavely warped substrate 276 and the convexly warped substrate 277 during the dechucking operation in FIG. 2B are mirror images of the lines for the concavely warped substrate 271 and the convexly warped substrate 272 in FIG. 2A. Though, in other embodiments, the dechucking capacitance profile (with respect to voltage) may be different than the chucking capacitance profile (with respect to voltage).

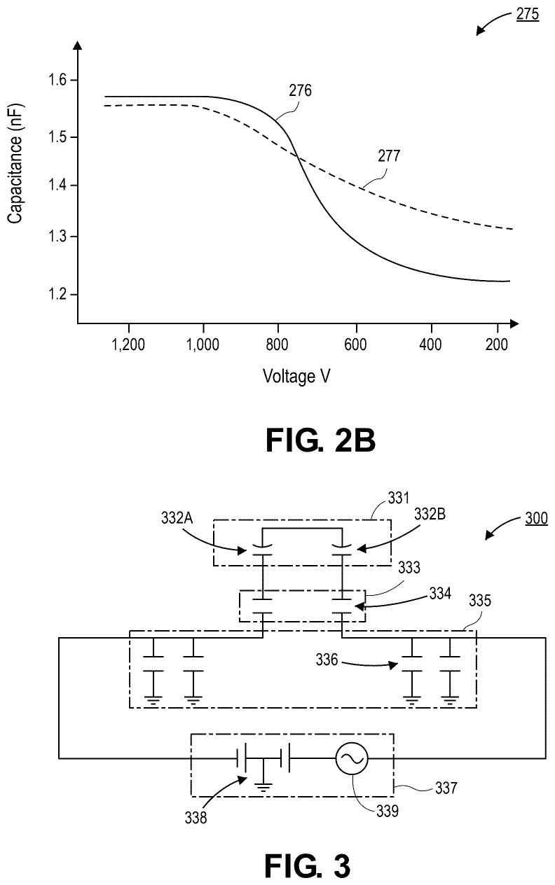

In order to account to the variable response of capacitance with respect to voltage changes, embodiments disclosed herein include an ESC that incorporates a capacitance sensor. The capacitance sensor can then be used in a feedback control loop in order to control the voltage ramp in order to chuck and dechuck substrates from the ESC. A schematic illustration of such an ESC is shown in FIG. 3.

Referring now to FIG. 3, an equivalent circuit diagram of an ESC 300 is shown, in accordance with an embodiment. In an embodiment, the ESC 300 comprises a capacitive sensor 337. In an embodiment, the capacitive sensor 337 comprises a DC power source. Additionally, an AC source 339 is provided for capacitance measurement purposes. In an embodiment, a DC power supply 338 within the sensor 337.

In an embodiment, the sensor 337 is electrically coupled to the electrodes (not shown). The electrodes and the substrate (not shown) form capacitive elements 332A and 332B at the electrode/substrate interface 331. The measurement of the capacitance of the capacitance elements 332A and 332B can be used in order to calculate an average distance of the substrate from the electrodes. In an embodiment, the electrical path between the interface 331 and the sensor 337 can include the equivalent capacitance 334 of any structures within the pedestal. For example, the equivalent capacitance 334 may be related to capacitance introduced into the system by heating elements 333 that are embedded in the pedestal of the ESC.

In an embodiment, a filter structure 335 may also be provided between the interface 331 and the sensor 337. In an embodiment, the filter structure may be used to filter RF noise that is generated by plasma over the ESC. For example, filter circuitry 336 may include any suitable passive components (e.g., resistors, capacitors, inductors, etc.) in order to effectively reduce any RF noise in the system. For example, grounded capacitors are shown as part of the filter circuitry 336 in FIG. 3. In an embodiment, the filter structure 335 may comprise a dedicated filter for each of the electrodes within the ESC 300.

Once the capacitance of the interface between the substrate and the electrodes can be measured, a closed loop control process can be implemented in order to provide efficient and controlled chucking and dechucking. As will be described in greater detail below, this can be accomplished by dynamically changing a voltage ramp rate in order to provide an approximately linear (or more linear) change to the average distance between the substrate and the ESC.

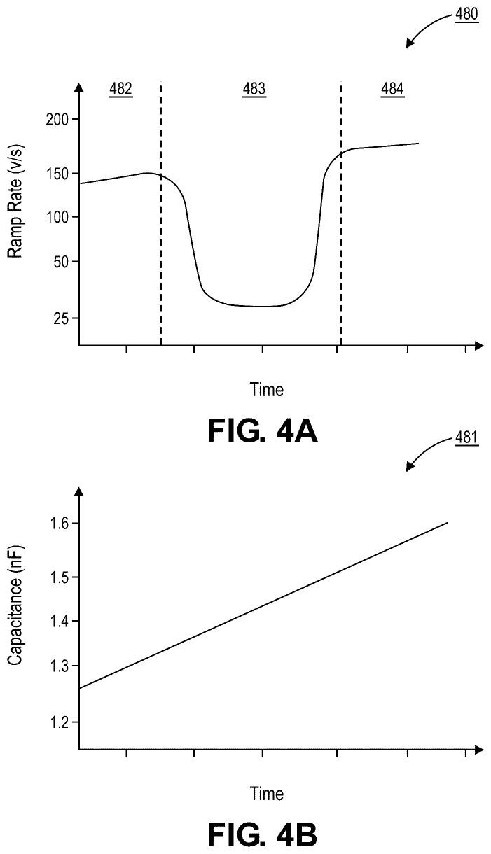

An example of a dynamic voltage ramp rate is shown in the plot 480 of FIG. 4A. As shown, the voltage ramp rate may begin initially at a relative fast rate at region 482. Region 482 may correspond to the slow change in capacitance to the left of region 273 in FIG. 2A. A high voltage ramp rate may be suitable for region 482 since relatively large increases in voltage at this region 482 may not produce significant changes in capacitance (or average distance between the substrate and the ESC).

Subsequently, region 483 shows a significant decrease in the voltage ramp rate. Region 483 may correspond with region 273 in FIG. 2A. As shown in FIG. 2A, relatively small voltages changes result in significant changes in capacitance (or average distance between the substrate and the ESC). Accordingly, moving through this region of voltage slower (i.e., at a lower voltage ramp rate) allows for a more gradual change in the curvature in the substrate. This can provide an overall reduction in mechanical and/or thermal shock since the material of the substrate has more time to adjust to the structural and/or thermal changes.

Finally, region 484 shows an increase in the voltage ramp rate. Region 484 may correspond to the slow change in capacitance to the right of region 273 in FIG. 2A. A high voltage ramp rate may be suitable for region 484 since relatively large increases in voltage at this region 484 may not produce significant changes in capacitance (or average distance between the substrate and the ESC).

Referring now to FIG. 4B, an idealized plot 481 of the capacitance between the substrate and the ESC versus time, is shown, in accordance with an embodiment. In an embodiment, the continuous adjustment of the voltage ramp rate may result in a substantially linear increase in capacitance in the case of a chucking operation. A substantially linear decrease in capacitance may be provided during a dechucking operation. While an idealized version may include a perfectly linear line, it is to be appreciated that no control system is perfect, and reasonable deviations from a linear line may be expected. In an embodiment, the plot 481 may be referred to as a capacitance profile (with respect to time).

Further, it is to be appreciated that some embodiments may not target a linear change in the capacitance. Depending on one or more of the structure of the substrate, the layers provided on the substrate, materials used for the substrate, etc., different capacitance profiles (with respect to time) may be targeted in order to minimize damage to the substrate and/or layers on the substrate. For example, if it is determined that damage is most likely to occur during initial reductions in warpage, then the rate of warpage reduction may be slowed for the beginning of the chucking operation relative to the rest of the chucking operation. That is, the capacitance based closed loop control of the chucking (or dechucking) process may be used to match any desired warpage reduction capacitance profile (with respect to time), in accordance with embodiments disclosed herein.

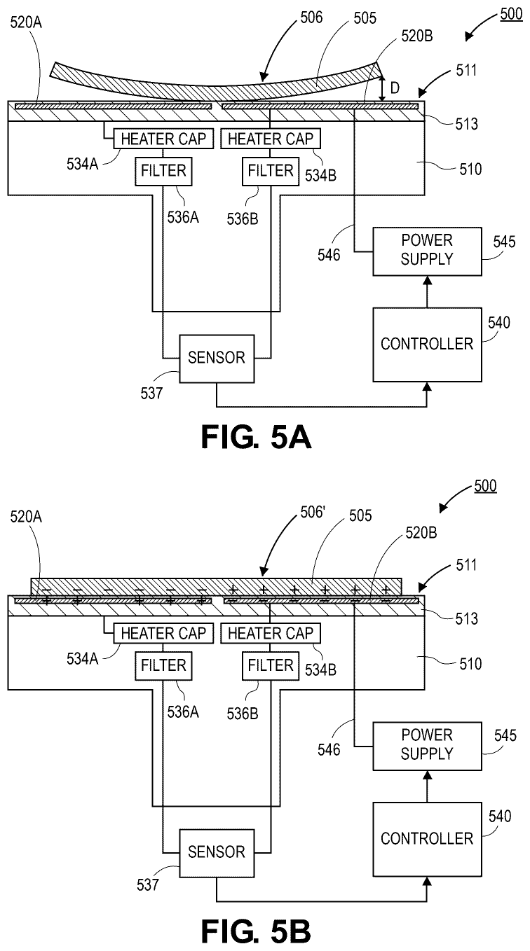

Referring now to FIGS. 5A and 5B, cross-sectional illustrations of a bipolar ESC 500 with an integrated capacitance sensor 537 and controller 540 are shown, in accordance with an embodiment. In FIG. 5A, the substrate 505 is not chucked, and a concave surface 506 faces away from the support surface 511 of the dielectric layer 513 of the pedestal 510. The edge of the substrate 505 may be a distance D away from the support surface 511 that is up to approximately 3 mm.

In an embodiment, a pair of electrode 520A and 520B may be embedded in the dielectric layer 513 and spaced away from the support surface 511. The electrodes 520A and 520B may be electrically coupled to a capacitance sensor 537. In an embodiment, the capacitive sensor 537 may include an AC source for implementing the capacitive measurements. The capacitance sensor 537 may be similar to any of the capacitance sensors described herein. In an embodiment, filters 536A and 536B may also be provided between the electrodes 520A and 520B and the capacitance sensor 537. The filters 536A and 536B may be RF filters to remove noise generated by the plasma or any other RF source. The effective heater capacitances 534A and 534B are also illustrated in FIG. 5A. While there may not be any discrete capacitor components in the pedestal heater (not shown), the presence of the heater may provide an effective capacitance that could otherwise alter the measurement. Therefore, the capacitance added by the presence of the heater may need to be accounted for by the controller 540 (or by the sensor 537).

In an embodiment, the sensor 537 may be communicatively coupled to a controller 540. The controller 540 may implement the closed loop control of the chucking (or dechucking) process. For example, capacitance feedback from the capacitance sensor 537 may be used by the controller 540 in order to control the voltage ramp rate supplied by the power supply 545 to the electrodes 520A and 520B. In FIG. 5A, an electrical connection 546 is shown from the power supply 545 to the electrode 520B. However, there may also be an electrical connection between the power supply 545 and the electrode 520A, or a second power supply (not shown) may be controlled by the controller 540 and electrically coupled to the electrode 520A.

In an embodiment, the controller 540 may include any computing system capable of implementing a closed loop control of the ESC 500. For example, the controller 540 may include a processor, a memory, and any other suitable components. An algorithm implemented in one or more of software, firmware, or hardware may execute the closed loop control. For example, the closed loop control may include a process similar to the process 860 that will be described in greater detail herein. The controller 540 may be part of the ESC 500, or the controller 540 may be an external system that is communicatively coupled to the ESC 500.

Referring now to FIG. 5B, a cross-sectional illustration of the bipolar ESC 500 after chucking is completed is shown, in accordance with an embodiment. As shown, the concave surface 506 has been flattened into planar surface 506′. Additionally, the substrate 505 is biased (e.g., negatively biased on the left side and positively biased on the right side). The bias in the substrate 505 is induced by the biases applied to the electrode 520A (positive bias) and the electrode 520B (negative bias).

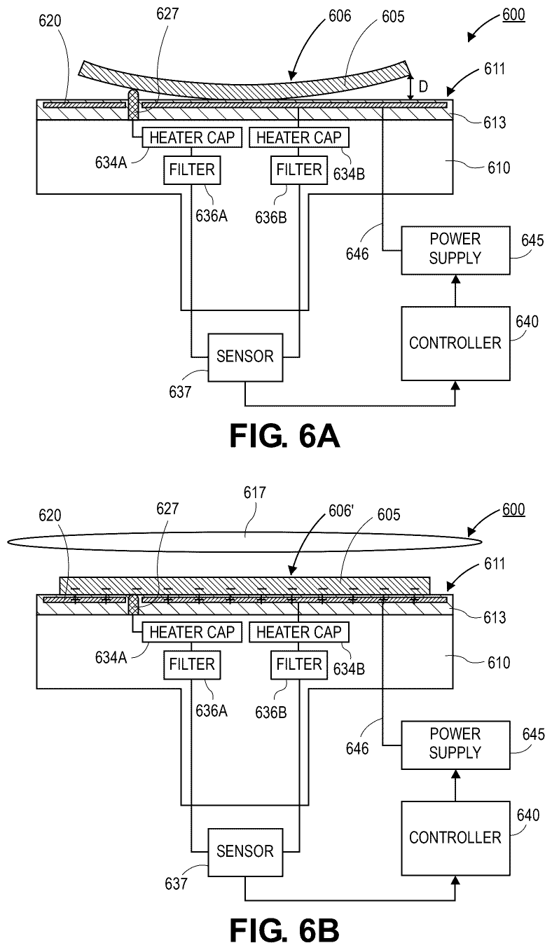

Referring now to FIGS. 6A and 6B, cross-sectional illustrations of a monopolar ESC 600 with an integrated capacitance sensor 637 and controller 640 are shown, in accordance with an embodiment. In FIG. 6A, the substrate 605 is not chucked, and a concave surface 606 faces away from the support surface 611 of the dielectric layer 613 of the pedestal 610. The edge of the substrate 605 may be a distance D away from the support surface 611 that is up to approximately 3.0 mm.

In an embodiment, a single electrode 620 may be embedded in the dielectric layer 613 and spaced away from the support surface 611. The electrode 620 may be electrically coupled to a capacitance sensor 637. The capacitance sensor 637 may be similar to capacitance sensor 537 described above. A second electrical connection to the capacitance sensor 637 may be made to the substrate 605 by an electrically conductive pin 627 that is electrically isolated from the electrode 620. The pin 627 may be retractable so that it can extend up past the support surface 611 to contact a raised surface of the substrate 605. However, during chucking the pin 627 can be pushed down as the substrate 605 is pulled towards the electrode 620.

In an embodiment, filters 636A and 636B may also be provided between the pin 627 and the capacitance sensor 637, and between the electrode 620 and the capacitance sensor 637. The filters 636A and 636B may be RF filters to remove noise generated by the plasma or any other RF source. The effective heater capacitances 634A and 634B are also illustrated in FIG. 6A. While there may not be any discrete capacitor components in the pedestal heater (not shown), the presence of the heater may provide an effective capacitance that could otherwise alter the measurement. Therefore, the capacitance added by the presence of the heater may need to be accounted for by the controller 640 (or by the sensor 637).

In an embodiment, the sensor 637 may be communicatively coupled to a controller 640. The controller 640 may implement the closed loop control of the chucking (or dechucking) process. For example, capacitance feedback from the capacitance sensor 637 may be used by the controller 640 in order to control the voltage ramp rate supplied by the power supply 645 to the electrodes 620 through electrical interconnect 646. In an embodiment, the controller 640 may be similar to the controller 540 described above.

Referring now to FIG. 6B, a cross-sectional illustration of the monopolar ESC 600 after chucking is completed is shown, in accordance with an embodiment. As shown, the concave surface 606 has been flattened into planar surface 606′. Additionally, the substrate 605 is biased (e.g., negatively biased as a result of the presence of the plasma 617). The bias in the substrate 605 may be induced by the bias applied to the electrode 620 (positive bias).

In FIGS. 6A and 6B, a pin 627 is used to make contact with the substrate 605 in order to obtain capacitance readings by the sensor 637. Though, in other embodiments, a monopolar ESC 600 may couple a first side of the sensor 637 to the electrode 620 and a second side of the sensor 637 to a chamber ground (not shown). In such an embodiment, the capacitance measurement may include a capacitance attributable to the plasma in addition to the capacitance between the electrode 620 and the substrate 605. However, the capacitance of the plasma can be determined (e.g., analytically) in order to subtract out the portion of the capacitance of the plasma to provide a measurement of the capacitance between the electrode 620 and the substrate 605. As such, embodiments disclosed herein may not require the presence of a pin that directly contacts the substrate 605 in order to make capacitance readings related to the warpage of the substrate 605 in a monopolar ESC embodiment.

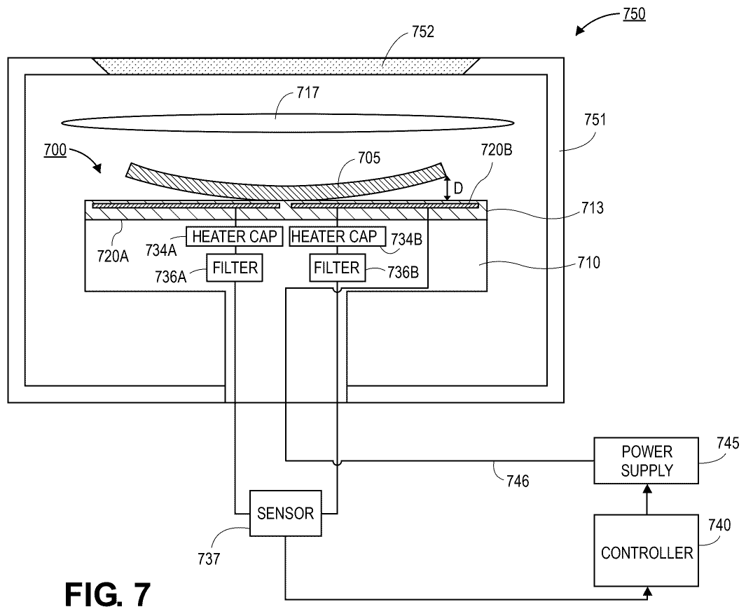

Referring now to FIG. 7, a cross-sectional illustration of a tool 750 for processing substrate 705 is shown, in accordance with an embodiment. The tool 750 may be any tool suitable for processing substrates, such as a deposition tool, an etching tool, a plasma treatment tool, a thermal treatment tool, or the like. The tool 750 is shown as supporting a plasma 717. Though, the tool 750 may also operate without a plasma in the case of a bipolar ESC 700 architecture. In an embodiment, the tool 750 may comprise a chamber 751. The chamber 751 may be suitable for forming and supporting a vacuum environment within the chamber 751. For example, vacuum pumps, exhaust systems, etc. may be included in the tool. In an embodiment, the tool 750 may comprise a lid 752 for sealing the chamber 751. The lid 752 may be a showerhead for introducing processing gasses into the chamber 751. The lid 752 may also be coupled to an RF power source or a microwave power source to generate and sustain the plasma 717 within the chamber 751.

In an embodiment, an ESC 700 may be provided in the chamber 751 for supporting the substrate 705. The ESC 700 may be similar to any of the ESCs described in greater detail herein. For example, the ESC 700 may comprise a pedestal 710 with a top dielectric layer 713. Electrodes 720A and 720B may be embedded in the dielectric layer 713. The substrate 705 may be warped with an edge that is spaced a distance D from the dielectric layer 713. Though, a concavely warped substrate 705 may also be used in some embodiments.

In an embodiment, the ESC 700 may comprise a capacitance sensor 737 and associated circuitry. For example, RF filters 736A and 736B may be provided. Heaters (which generate heater capacitance 734A and 734B) may also be included in the pedestal 710. In an embodiment, the capacitance sensor 737 may be communicatively coupled to a controller 740. The controller 740 may implement a capacitance based closed loop control of a power supply 745. The power supply 745 may be coupled to one or both electrodes 720A and 720B through an electrical interconnect 746. The closed loop control of the power supply 745 may result in a controlled chucking and/or dechucking process similar to any of the chucking and/or dechucking processes described in greater detail herein.

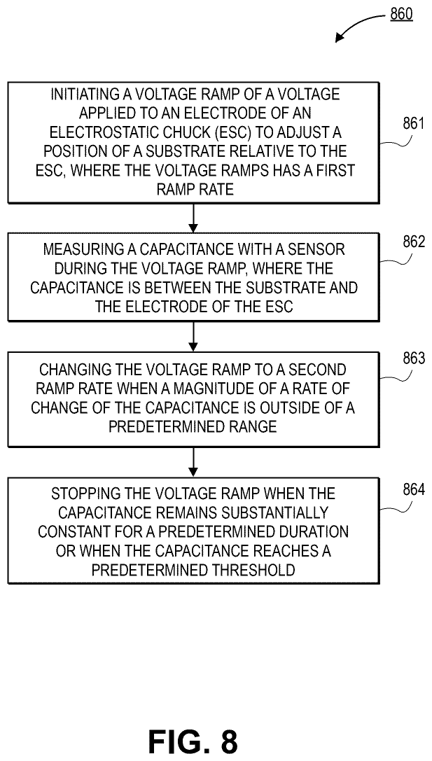

Referring now to FIG. 8, a process flow diagram of a process 860 for chucking and/or dechucking a warped substrate with an ESC through closed loop control with capacitance feedback is shown, in accordance with an embodiment. In an embodiment, the process 860 may be implemented with ESCs similar to any of the ESCs described in greater detail herein.

In an embodiment, the process 860 may begin with operation 861, which comprises initiating a voltage ramp of a voltage applied to an electrode of an electrostatic chuck (ESC) to adjust a position of a substrate relative to the ESC. In an embodiment, the voltage ramp has a first ramp rate. In the case of chucking the substrate, the voltage ramp is a positive voltage ramp, and in the case of dechucking the substrate, the voltage ramp is a negative voltage ramp. In an embodiment the substrate may be warped (e.g., convexly warped or concavely warped).

In an embodiment, the process 860 may continue with operation 862, which comprises measuring a capacitance with a sensor during the voltage ramp. In an embodiment, the capacitance that is measured is the capacitance generated between the substrate and the electrode of the ESC. The measured capacitance in operation 862 may be proportional to an average distance between the surface of the substrate and the electrode. In an embodiment, the capacitance measurement may be implemented by a sensor with an AC source. RF filters may also be provided in order to filter out any stray RF noise introduced into the system (e.g., by a plasma).

In an embodiment, the process 860 may continue with operation 863, which comprises changing the voltage ramp to a second ramp rate when a magnitude of a rate of change of the capacitance is outside of a predetermined range. The predetermined range may be chosen based on one or more factors, such as how sensitive the substrate is to damage (e.g., lower ranges may be necessary for more sensitive substrates), how fast the chucking or dechucking operation needs to be (e.g., larger ranges may be used when faster chucking/dechucking operations are needed), how much the substrate is warped (e.g., lower ranges may be used to protect from damage in more severely warped substrates), temperature differences between the substrate and the ESC (e.g., lower ranges may be used for higher temperature differentials), or the like. In some embodiments, the predetermined range of the magnitude of a rate of change of the capacitance may be between approximately 0.01 nF/s to 0.1 nF/s. Though, any suitable range may be used depending on the needs of the particular substrate being chucked/dechucked.

In the process 860 shown in FIG. 8, the change from a first ramp rate to a second ramp rate is shown. However, it is to be appreciated that operations 862 and 863 may be repeated any number of times over the duration of the chucking/dechucking operation. For example, capacitance measurements may be taken at any interval (e.g., every 0.01 seconds, every 0.1 seconds, every second, every 10 seconds, etc.), and an additional change to the ramp rate may be made whenever the magnitude of the rate of change of the capacitance is outside of the predetermined range. That is, operations 862 and 863 may operate in a closed loop control fashion in order to provide enhanced control of the chucking/dechucking operation, as described herein.

In an embodiment, a plot of the capacitance over time during the repeated loop of operations 862 and 863 may be substantially linear. Though, the plot of the capacitance over time may have any desired shape, as described in greater detail herein. In some embodiments, a non-linear plot of capacitance over time may be generated by having a predetermined range that changes throughout the duration of the chucking/dechucking operation. For example, a chucking/dechucking operation may have a first predetermined range at a beginning of the operation, a second predetermined range at a middle of the operation, and a third predetermined range at an end of the operation. In some embodiments, one or more of the first predetermined range, the second predetermined range, or the third predetermined range may be different from the others.

In an embodiment, the predetermined range may be set through the use of a machine learning (ML) and/or artificial intelligence (AI) system. For example, a controller implementing the process 860 may monitor and record the chucking and/or dechucking behavior of multiple substrates in a lot (or any sample size of substrates). This data can be leveraged by an ML and/or AI system to dynamically alter the predetermined range of the magnitude of a rate of change of the capacitance. As such, portions of the process 860 that have been determined to be more sensitive (as a result of analysis of the data by the ML and/or AI system) can include a predetermined range that is tighter than a predetermined range of portions of the process 860 that have been determined to be less sensitive (as a result of analysis of the data by the ML and/or AI system).

In an embodiment, the process 860 may continue with operation 864, which comprises stopping the voltage ramp when the capacitance remains substantially constant for a predetermined duration, or when the capacitance reaches a predetermined threshold. For example, a constant capacitance over time may indicate that the substrate is fully chucked (or sufficiently chucked). This can prove beneficial when the precise voltage for sufficient chucking is not known. For example, wear of the ESC or differences between substrates may result in changes to the final chucking voltage over the lifespan of the ESC. This can prevent overchucking, which may negatively impact or damage the substrate and/or the ESC. However, in some instances, the operation 864 is stopped at a predetermined voltage threshold.

Embodiments disclosed herein may also incorporate ML and/or AI systems that enable direct correlation between capacitance readings from the sensor to on substrate performance (e.g., deposition uniformity, etch uniformity, etc.). For example, after a substrate is processed, the metrology data may be obtained. Over the course of obtaining metrology data between a plurality of substrates, an ML and/or AI system may identify correlations between the metrology data and the capacitance readings during chucking and/or dechucking. As such, on substrate performance of subsequently processed substrates may be predicted through the use of the capacitance readings by the sensor. Additionally, some embodiments may use ML and/or AI systems to actively control the capacitance profile over time to obtain a desired on substrate performance.

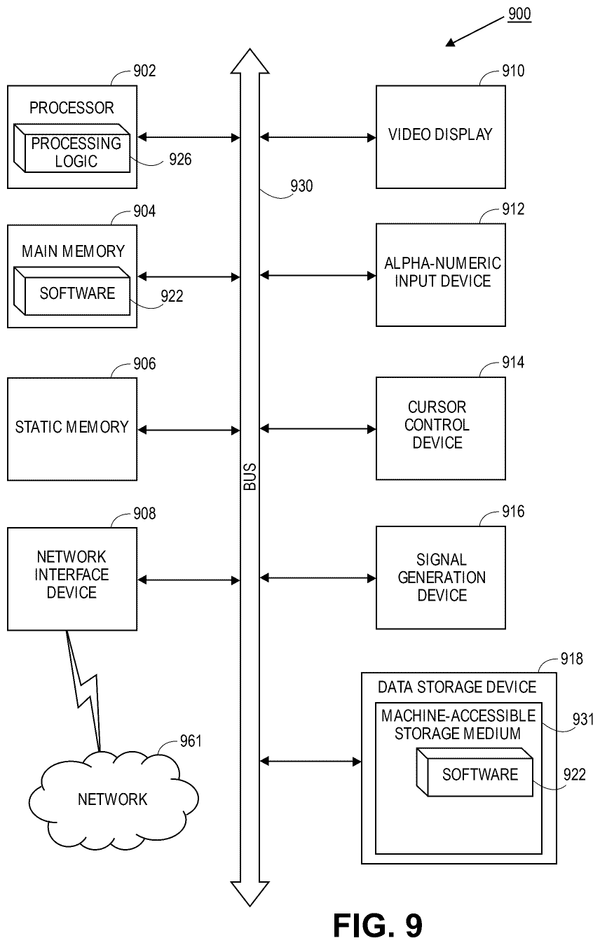

Referring now to FIG. 9, a block diagram of an exemplary computer system 900 of a processing tool is illustrated in accordance with an embodiment. In an embodiment, computer system 900 is coupled to and controls processing in the processing tool. The computer system 900 may be communicatively coupled to one or more vapor concentration sensor modules, such as those disclosed herein. The computer system 900 may utilize outputs from the one or more vapor concentration sensor modules in order to modify one or more parameters, such as, for example, processing recipe parameters, cleaning schedules for the processing tool, component replacement determinations, and the like.

Computer system 900 may be connected (e.g., networked) to other machines in a Local Area Network (LAN), an intranet, an extranet, or the Internet. Computer system 900 may operate in the capacity of a server or a client machine in a client-server network environment, or as a peer machine in a peer-to-peer (or distributed) network environment. Computer system 900 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 900, the term “machine” shall also be taken to include any collection of machines (e.g., computers) that individually or jointly execute a set (or multiple sets) of instructions to perform any one or more of the methodologies described herein.

Computer system 900 may include a computer program product, or software 922, having a non-transitory machine-readable medium having stored thereon instructions, which may be used to program computer system 900 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 900 includes a system processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

System processor 902 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 902 may also be one or more special-purpose processing devices such as an application specific integrated circuit (ASIC), a field programmable gate array (FPGA), a digital signal system processor (DSP), network system processor, or the like. System processor 902 is configured to execute the processing logic 926 for performing the operations described herein.

The computer system 900 may further include a system network interface device 908 for communicating with other devices or machines. The computer system 900 may also include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium 931 (or more specifically a computer-readable storage medium) on which is stored one or more sets of instructions (e.g., software 922) embodying any one or more of the methodologies or functions described herein. The software 922 may also reside, completely or at least partially, within the main memory 904 and/or within the system processor 902 during execution thereof by the computer system 900, the main memory 904 and the system processor 902 also constituting machine-readable storage media. The software 922 may further be transmitted or received over a network 961 via the system network interface device 908. In an embodiment, the network interface device 908 may operate using RF coupling, optical coupling, acoustic coupling, or inductive coupling.

While the machine-accessible storage medium 931 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include ESCs with capacitance sensors to implement closed loop control of chucking and/or dechucking operations through the use of capacitance as a feedback input.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a pedestal with a support surface configured to support a substrate;
an electrode embedded within the pedestal below the support surface;
a sensor electrically coupled to the electrode, wherein the sensor is configured to measure a capacitance between the electrode and the substrate when the substrate is provided on the support surface; and
a radio frequency (RF) filter electrically coupled between the electrode and the sensor.

2. The apparatus of claim 1, wherein the sensor comprises a direct current (DC) power supply with an alternating current (AC) source.

3. The apparatus of claim 1, wherein the RF filter comprises one or more grounded capacitors.

4. The apparatus of claim 1, wherein the pedestal further comprises a heating element.

5. The apparatus of claim 1, further comprising a second electrode, wherein the second electrode is electrically coupled to the sensor.

6. The apparatus of claim 5, wherein the apparatus is a bipolar electrostatic chuck (ESC).

7. The apparatus of claim 1, further comprising a retractable pin that passes through the support surface and is electrically isolated from the electrode, and wherein the retractable pin is electrically coupled to the sensor.

8. The apparatus of claim 7, wherein the apparatus is a monopolar electrostatic chuck (ESC).

9. A method, comprising:
initiating a voltage ramp of a voltage applied to an electrode of an electrostatic chuck (ESC) to adjust a position of a substrate relative to the ESC, wherein the voltage ramp has a first ramp rate;
measuring a capacitance with a sensor during the voltage ramp, wherein the capacitance is between the substrate and the electrode of the ESC; and
changing the voltage ramp to a second ramp rate when a magnitude of a rate of change of the capacitance is outside of a predetermined range.

10. The method of claim 9, wherein the method is a chucking operation for securing the substrate to the ESC.

11. The method of claim 9, wherein the method is a dechucking operation for releasing the substrate from the ESC.

12. The method of claim 9, further comprising:
stopping the voltage ramp when the capacitance remains substantially constant for a predetermined duration.

13. The method of claim 9, further comprising:
stopping the voltage ramp when the capacitance reaches a predetermine threshold.

14. The method of claim 9, further comprising:
implementing a feedback control loop after changing the voltage ramp to a second ramp rate, wherein the feedback control loop comprises:
repeatedly measuring the capacitance; and
changing a ramp rate whenever the magnitude of the rate of change of the capacitance is outside of the predetermined range.

15. The method of claim 14, wherein the predetermined range is dynamically changed by a machine learning (ML) and/or an artificial intelligence (AI) system.

16. The method of claim 14, wherein the feedback control loop provides a change in the capacitance over time that is substantially linear.

17. The method of claim 9, wherein the substrate is initially bowed with a curve that faces toward the ESC or away from the ESC.

18. An apparatus, comprising:
a chamber; and
an electrostatic chuck (ESC) within the chamber, wherein the ESC comprises:
an electrode embedded within a pedestal below a support surface;
a sensor electrically coupled to the electrode, wherein the sensor is configured to measure a capacitance between the electrode and a substrate when the substrate is provided on the support surface;
a radio frequency (RF) filter electrically coupled between the electrode and the sensor; and
a controller communicatively coupled to the sensor, wherein the controller is configured to provide feedback control of a chucking or dechucking process based on capacitance readings provided by the sensor.

19. The apparatus of claim 18, wherein the ESC is a bipolar ESC.

20. The apparatus of claim 18, wherein the ESC is a monopolar ESC.
